(19) United States
(12) Patent Application Publication
(10) Pub. No.: US 2025/0351485 A1
(43) Pub. Date: Nov. 13, 2025

(54) STRAINED CHANNEL REGIONS

(71) Applicant: Taiwan Semiconductor Manufacturing Company, Ltd., Hsinchu (TW)

(72) Inventors: Jung-Chien CHENG, Tainan (TW); Guan-Lin Chen, Hsinchu (TW); Shi Ning Ju, Hsinchu (TW); Kuo-Cheng CHIANG, Hsinchu (TW); Chih-Hao Wang, Hsinchu (TW)

(73) Assignee: Taiwan Semiconductor Manufacturing Company, Ltd., Hsinchu (TW)

(21) Appl. No.: 18/658,379

(22) Filed: May 8, 2024

(51) Int. Cl. H01L 29/06; H01L 21/8238; H01L 27/092; H01L 29/08; H01L 29/423; H01L 29/66; H01L 29/775; H01L 29/78; H01L 29/786

(52) U.S. Cl. CPC H10D 62/121; H10D 30/014; H10D 30/024; H10D 30/43; H10D 30/6211; H10D 30/6735; H10D 30/6757; H10D 62/151; H10D 64/017; H10D 84/0167; H10D 84/017; H10D 84/0193; H10D 84/038; H10D 84/853

(57) ABSTRACT

Provided are semiconductor devices with strained nanosheet channels and methods for fabricating such devices. A method includes forming a fin comprising a first material lying over a second material; forming a sacrificial gate over the fin, wherein a channel region of the fin including the first material and the second material lies directly under the sacrificial gate and between two non-channel regions of the fin including the first material and the second material; removing the non-channel regions of the fin; performing a process to replace the second material in the channel region of the fin with a third material; forming source/drain features in the non-channel regions; removing the sacrificial gate; removing the third material; and forming a gate over the fin.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far the demand has been met in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, reducing OFF-state current, and reducing short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFET devices and GAA devices are compatible with conventional complementary metal-oxide-semiconductor (CMOS) processes. Further, the three-dimensional structure of such devices allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a semiconductor device, in accordance with some embodiments.

FIG. 2 is a flow chart illustrating a method, in accordance with some embodiments.

FIGS. 3-30 are perspective or cross-sectional views of the semiconductor device during successive stages of fabrication according to the method of FIG. 2, in accordance with some embodiments.

FIG. 31 is a flow chart illustrating a method, in accordance with some embodiments.

FIGS. 32-45 are perspective or cross-sectional views of the semiconductor device during successive stages of fabrication according to the method of FIG. 31, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, at least 75 wt. % of the identified material, or at least 90 wt. % of the identified material, or substantially 100 wt. % of the identified material; and a layer that is a “material” includes at least 50 wt. % of the identified material, for example at least 60 wt. % of the identified material, at least 75 wt. % of the identified material, or at least 90 wt. % of the identified material, or substantially 100 wt. % of the identified material. For example, certain embodiments, each of a titanium nitride layer and a layer that is titanium nitride is a layer that is at least 50 wt. %, at least 60 wt. %, at least 75 wt. %, titanium nitride, or at least 90 wt. %, or substantially 100 wt. %, titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

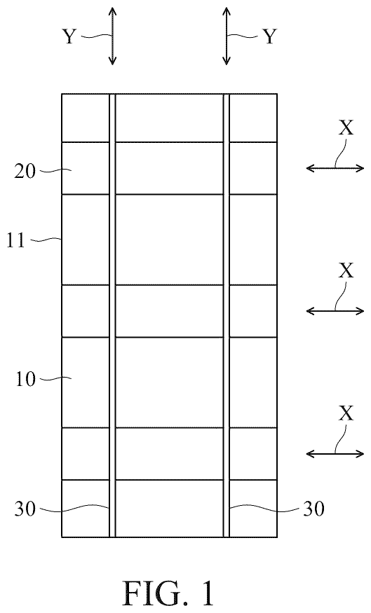

FIG. 1 illustrates a unit cell 11, i.e., a portion of the semiconductor substrate 10 in a semiconductor device 100. As shown, parallel active regions 20 are spaced apart from one another and extend in an X-direction. Further, parallel gate lines 30 are spaced apart from one another and extend in a Y-direction perpendicular to the X-direction. Gate lines 30 may be formed from conductive material such as metal and form gate structures for the device 100.

The semiconductor device 100 may be a multi-gate device 100. In various embodiments, the multi-gate device 100 may include a FinFET device, a GAA transistor, or other type of multi-gate device. The multi-gate device 100 is formed over a substrate 10.

The multi-gate devices 100 may include a P-type metal-oxide-semiconductor device 100 or an N-type metal-oxide-semiconductor multi-gate device 100. Specific examples may be presented and referred to herein as FinFET devices 100, on account of their fin-like structure. Also presented herein are embodiments of a type of multi-gate transistor referred to as a gate-all-around (GAA) device 100. A GAA device 100 includes any device that has its gate structure, or portion thereof, formed on four sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, the term “nanosheet channel” is intended to include nanowire channel and bar-shaped channel configurations.

In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

Presented herein are embodiments of devices that may have one or more channel regions (e.g., nanosheets) associated with a gate structure. For example, a stack of vertically spaced nanosheet channels may be provided. However, one of ordinary skill would recognize that the teaching can apply to a single channel (e.g., single nanosheet) or any number of channels. One of ordinary skill may recognize other examples of semiconductor devices that may benefit from aspects of the present disclosure.

In certain embodiments, an interposer layer is used to apply stress forces to a nanosheet channel to form a strained nanosheet channel. In certain embodiments, an interposer layer is used to prevent or reduce damage to the nanosheet channel during formation of a gate cavity around the nanosheet channel before gate metal deposition. In certain embodiments, diffusion out of the semiconductor nanosheet is prevented or reduced.

As described herein, in some embodiments, processes are performed to provide strained nanosheet channels. Specifically, certain processes involve applying a stress to a nanosheet channel to form a strained nanosheet channel. In certain embodiments, a sacrificial layer lying under, or sacrificial layers lying under and over, a semiconductor nanosheet are at least partially removed. The remaining portion of the sacrificial layer and/or a newly introduced interposer layer are then processed to cause expansion. This expansion applies stress to the semiconductor nanosheet.

In certain embodiments, an interposer layer is formed under or under and over a semiconductor nanosheet. Later, the interposer layer is removed. In certain embodiments, removal of the interposer layer is performed by a highly selective process such that little or none of the semiconductor nanosheet is removed by the process.

Further, the interposer layer may block diffusion out of the semiconductor nanosheet. For example, the sacrificial layer may be a germanium source like silicon germanium (SiGe). When a germanium source is present during later processing of an n-type gate, such as during thermal processing, germanium may diffuse from the sacrificial layer to a phosphorus-doped n-type source/drain feature and may enhance diffusion of phosphorus from the n-type source/drain feature to the sacrificial layer. As a result, n-type mobility may be reduced. High n-type doping levels may generate increased interdiffusion.

In embodiments herein, such diffusion and mobility loss are avoided by removing the germanium source before the thermal processing. Specifically, certain embodiments remove the sacrificial layer of silicon germanium from the channel region. Then, a germanium-free interposer layer may be formed in place of the silicon germanium layer. In other embodiments, a silicon germanium layer may be converted to a silicon germanium oxide layer. For example, in certain embodiments, a material with a higher dielectric value may be formed to replace the original silicon germanium layer. Diffusion may be reduced through such a conversion or replacement.

Embodiments of the present disclosure offer advantages over the existing art, though it is understood that other embodiments may offer different advantages, not all advantages are necessarily discussed herein, and no particular advantage is required for all embodiments.

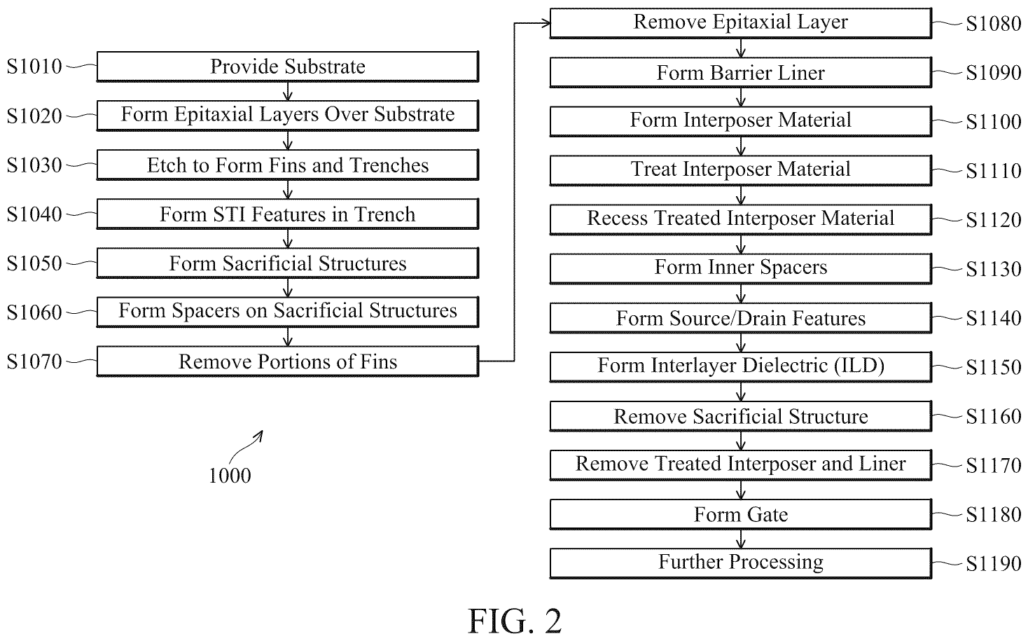

Referring to FIG. 2, illustrated therein is a method 1000 of fabrication of a semiconductor device 100 (such as a multi-gate device), in accordance with various embodiments. Method 1000 is discussed below with reference to a GAA device having a channel region that may be referred to as a nanosheet or nanosheet channel and which may include various geometries (e.g., cylindrical, bar-shaped) and dimensions. However, it will be understood that aspects of method 1000 may be equally applied to other types of multi-gate devices without departing from the scope of the present disclosure. In some embodiments, method 1000 may be used to fabricate the multi-gate device 100, described above with reference to FIG. 1. Thus, one or more aspects discussed above with reference to the multi-gate device 100 may also apply to method 1000. It is understood that method 1000 includes steps having features of a complementary metal-oxide-semiconductor (CMOS) technology process flow and thus, are only described briefly herein. Also, additional steps may be performed before, after, and/or during method 1000.

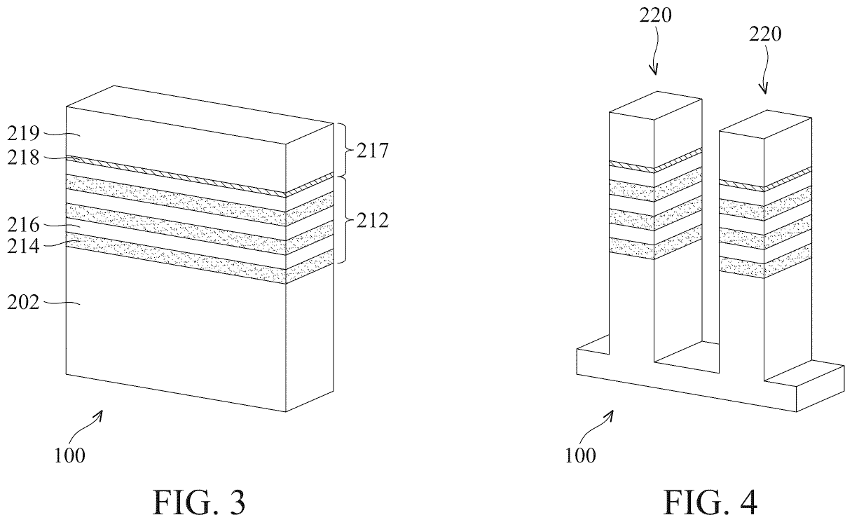

Method 1000 is described below with reference to FIGS. 3-30, which provide perspective views of the multi-gate device 100, cross-sectional views of the multi-gate device 100 along a plane substantially parallel to a plane defined by the X and Z axes in FIG. 1, and ross-sectional views of the multi-gate device 100 along a plane substantially parallel to a plane defined by the Y and Z axes in FIG. 1, as described, illustrating various stages of fabrication according to method 1000.

Further, the semiconductor device 100 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the concepts of the present disclosure. In some embodiments, the semiconductor device 100 includes a plurality of semiconductor devices (e.g., transistors), including PFETs, NFETs, etc., which may be interconnected. Moreover, it is noted that the process steps of method 1000, including any descriptions given with reference to the figures are merely exemplary and are not intended to be limiting beyond what is specifically recited in the claims that follow.

At operation S1010, the method 1000 provides a substrate 202, as shown in FIG. 3. In some embodiments, the substrate 202 may be a semiconductor substrate such as a silicon (Si) substrate. The substrate 202 may include various layers, including conductive or insulating layers formed on a semiconductor substrate. The substrate 202 may include various doping configurations depending on design requirements as is known in the art. For example, different doping profiles (e.g., p-well, n-well) may be formed on the substrate 202 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. In the illustrated embodiment, the substrate 202 is made of crystalline Si.

As shown in FIG. 3, at operation S1020, the method 1000 (FIG. 2) forms one or more epitaxial layers over the substrate 202. In some embodiments, an epitaxial stack 212 is formed over the substrate 202. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. In an embodiment, the epitaxial layers 214 are silicon germanium (SiGe) and the epitaxial layers 216 are silicon. In embodiments wherein the epitaxial layer 214 includes SiGe and the epitaxial layer 216 includes silicon, the silicon oxidation rate is less than the SiGe oxidation rate. It is noted that three layers of epitaxial layers 214 and three layers of epitaxial layers 216 are illustrated in FIG. 3, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 100. In some embodiments, the number of epitaxial layers 216 is between two and ten, such as six or seven.

In some embodiments, the epitaxial layer 214 has a thickness ranging from about five nanometers to about fifteen nanometers. The epitaxial layers 214 may be substantially uniform in thickness. In some embodiments, the epitaxial layer 216 has a thickness ranging from about five nanometers to about fifteen nanometers. In some embodiments, the epitaxial layers 216 of the stack are substantially uniform in thickness. As described in more detail below, the epitaxial layer 216 may serve as channel region(s) for a subsequently formed multi-gate device and has a thickness chosen based on device performance considerations. The epitaxial layer 214 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 216 include the same material as the substrate 202. In some embodiments, the epitaxially grown layers 214 and 216 include a different material than the substrate 202. As stated above, in at least some examples, the epitaxial layer 214 includes an epitaxially grown Si₁₋ₓGeₓ layer (wherein x is from about 10 to about 55%) and the epitaxial layer 216 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

In some embodiments, the method includes forming a mask layer 217 over the epitaxial stack 212, as shown in FIG. 3. The mask layer 217 includes a first mask layer 218 and a second mask layer 219. A first mask layer 218 may be a pad oxide layer made of a silicon oxide, which may be formed by a thermal oxidation. A second mask layer 219 may be made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process.

As shown in FIG. 4, at operation S1030, the method 1000 (FIG. 2) patterns the epitaxial stack 212 to form semiconductor fins 220. For example, the mask layer 217 may be patterned into a mask pattern by using patterning operations including photolithography and etching. Operation S1030 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 216 are thereby patterned into the fin 220. Further, the substrate 202 under the layers 214 and 216 may be patterned such that a mesa portion 228 of the substrate 202 forms a lower portion of the fin 220. While FIG. 4 illustrates the formation of two fins 220, any suitable number of the fins may be formed. Trenches are etched between adjacent fins 220.

In various embodiments, each fin 220 includes an upper portion of the interleaved epitaxial layers 214 and 216, and a bottom portion that is formed from the etched substrate 202. Each fin 220 protrudes upwardly in the Z-direction from the substrate 202 and extends lengthwise in the X-direction. Sidewalls of each fin 220 may be straight or inclined (not shown). In FIG. 4, additional fins would be spaced apart along the Y-direction. The fins 220 may have a same width or different widths.

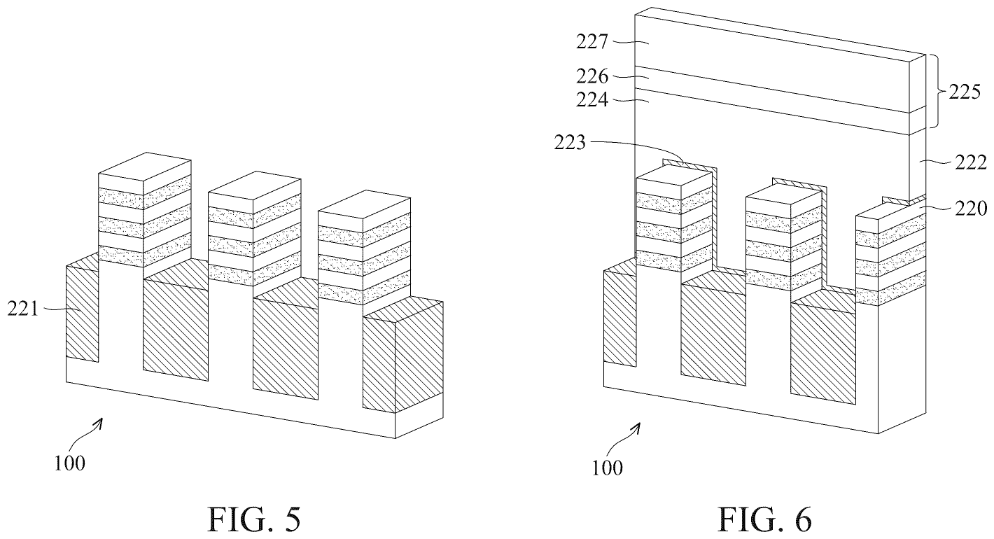

As shown in FIG. 5, at operation S1040, the method 1000 (FIG. 2) forms shallow trench isolation (STI) features (also denoted as STI features) 221 in trenches adjacent to each fin 220 with a dielectric layer. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 221, as shown in FIG. 5. In the illustrated embodiment, the STI features 221 are formed on the substrate 202. Any suitable etching technique may be used to recess the isolation features 221 including dry etching, wet etching, RIE, and/or other etching methods, and in a certain embodiments, an anisotropic dry etching is used to selectively remove the dielectric material of the isolation features 221 without etching the fin 220. The mask layer 217 (shown in FIG. 4) may also be removed before, during, and/or after the recessing of the isolation features 221. In some embodiments, the mask layer 217 is removed prior to the recessing of the isolation features 221. In some embodiments, the mask layer 217 is removed by an etchant used to recess the isolation features 221.

As shown in FIG. 6, at operation S1050, the method 1000 (FIG. 2) forms sacrificial (dummy) gate structures 222. FIG. 6 illustrates one half of a sacrificial gate structure 222. While FIG. 6 indicates the formation of one sacrificial gate structure 222, any suitable number of sacrificial gate structures may be formed. Each sacrificial gate structure 222 protrudes upwardly in the Z-direction from the substrate 202 and extends lengthwise in the Y-direction. In FIG. 6, additional sacrificial gate structures would be spaced apart along the X-direction.

The sacrificial gate structures 222 are formed over portions of the fin 220 which are to be channel regions. The sacrificial gate structures 222 may extend over a number of adjacent fins 220. The sacrificial gate structures 222 lie directly over and define the channel regions of the GAA devices to be formed. Each of the sacrificial gate structures 222 includes a sacrificial gate dielectric 223 and a sacrificial gate electrode 224 over the sacrificial gate dielectric 223.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from about one hundred nanometers to about two hundred nanometers in some embodiments. The sacrificial gate electrode layer includes silicon such as polycrystalline silicon or amorphous silicon. The thickness of the sacrificial gate dielectric layer is in a range from about one nanometer to about five nanometers in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, and as shown in FIG. 6, a patterning operation is performed on the mask layer 225, and the sacrificial gate electrode layers and the sacrificial gate dielectric layer are patterned into the sacrificial gate structures 222, including sacrificial gate dielectric layer 223 and sacrificial gate electrode 224.

After forming the sacrificial gate structures 222, each fin 220 is partially uncovered or exposed on opposite sides of the sacrificial gate structures 222, thereby defining source/drain (S/D) regions. In this disclosure, “source/drain region(s)” or “source/drain feature(s)” may refer to a source or a drain, individually or collectively dependent upon the context.

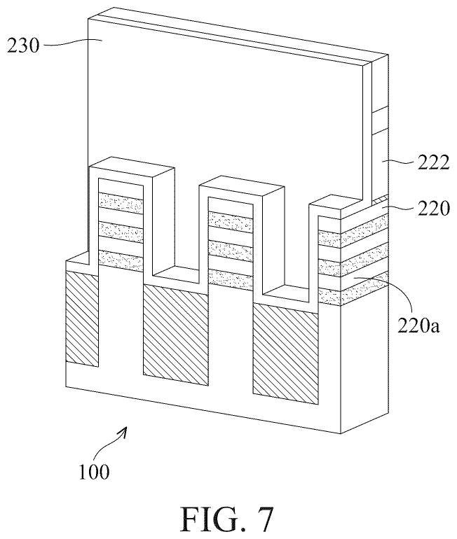

Referring now to FIG. 7, at operation S1060, the method 1000 (FIG. 2) forms spacers 230 on sidewalls of the sacrificial gate structures 222 and sidewalls of the fins 220 by depositing spacer materials, followed by an etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 may include multiple layers, such as a liner layer and a main spacer layer on the liner layer.

By way of example, the spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively.

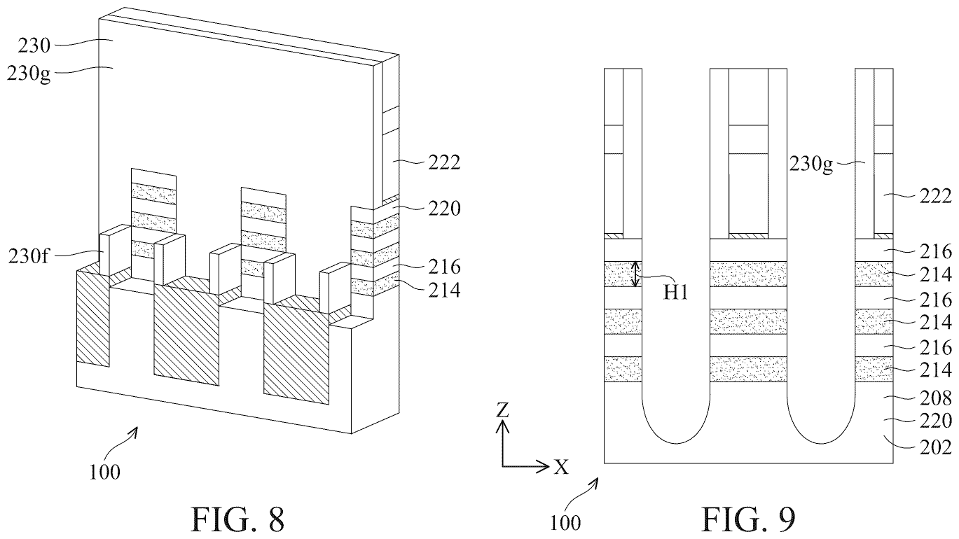

As shown in FIG. 8, the deposition of the liner material layer and the dielectric material layer are followed by, at operation S1070, etching-back (e.g., anisotropically) to expose, and remove, portions 220a of the fins 220 adjacent to and not covered by the sacrificial gate structure 222 (e.g., source/drain regions). FIG. 9 is an X-cut cross-sectional view of the stage of fabrication of FIG. 8, along a single fin 220 and across a central sacrificial gate 222 located between illustrated portions of two adjacent sacrificial gates 222.

Cross-referencing FIGS. 8 and 9, the liner material layer and the dielectric material layer may remain on the sidewalls of the sacrificial gate structure 222 as the gate sidewall spacers 230g, and on the sidewalls of the fins as the fin sidewall spacers 230f. In some embodiments, the etching-back process may include a wet etch process, a dry etch process, a multiple-step etch process, and/or a combination thereof. The spacers 230 may have a thickness ranging from about five nanometers to about twenty nanometers.

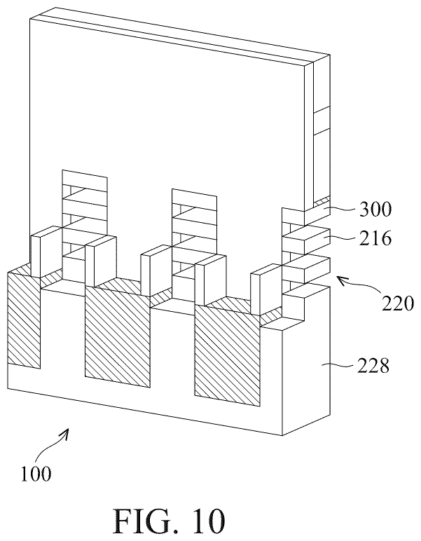

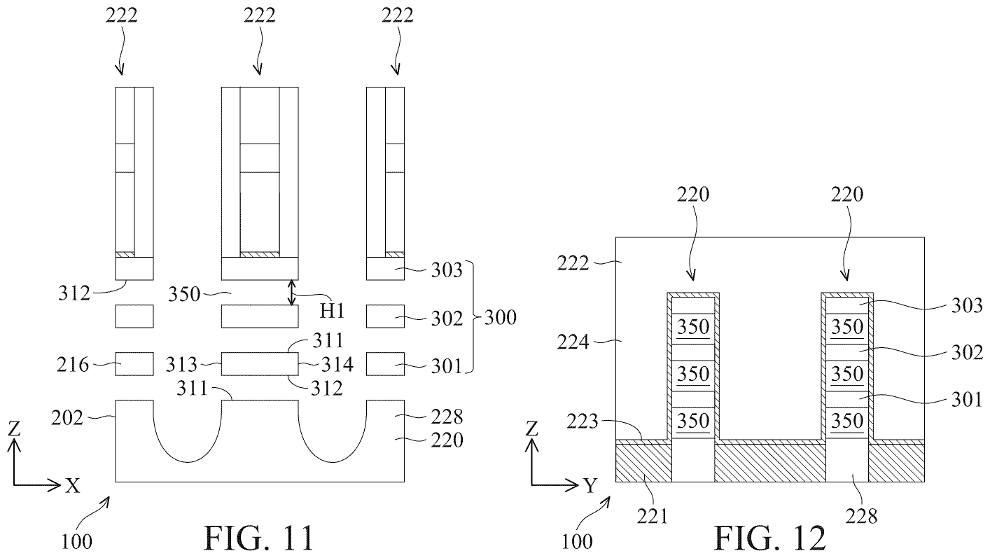

Method 1000 may continue, at operation S1080, with removing the epitaxial layers 214, i.e., the silicon germanium (SiGe) layers 214, as shown in FIG. 10. FIG. 11 is an X-cut cross-sectional view of the stage of fabrication of FIG. 10, along a single fin 220 and across a central sacrificial gate structure 222 between illustrated portions of two adjacent sacrificial gate structures 222. FIG. 12 is a Y-cut cross-sectional view of the stage of fabrication of FIG. 10, along sacrificial gate 222 and across two fins 220.

Cross-referencing FIGS. 10-12, after removal of the layers 214, layers 216 remain in the fins 220. In an embodiment in which the layers 214 are formed of silicon germanium (SiGe) and the layers 216 are formed of silicon (Si), the layers 214 may be removed, for example, by an NMOS SiGe removal process. In some embodiments, the removal process may use an etchant that etches the silicon germanium at a higher rate than the silicon, such as NH₄OH:H₂O₂:H₂O (ammonia peroxide mixture, APM), H₂SO₄+H₂O₂ (sulfuric acid peroxide mixture, SPM), or the like. Other suitable processes and materials may be used. This etching process removes the layers 214.

Nanosheets 300 are formed by the isolated layers 216 and define the fins 220, such as for an n-type device. The illustrated nanosheets 300 include a lowest nanosheet 301 adjacent the mesa portion, an intermediate nanosheet 302, and an uppermost nanosheet 303. In certain embodiments, there may be no intermediate nanosheet 303 or more than one intermediate nanosheet 303 in each fin 220. In certain embodiments, there may be only a single nanosheet 300 in each fin 220. Voids 350 are formed between vertically adjacent nanosheets 300. Each void 350 is bounded by an uppermost surface 311 (of mesa 228 or a respective nanosheet 300) and by a lowest surface 312 (of a respective nanosheet 300). Each surface 311 and 312 extends in the X-direction from a first end surface 313 to a second end surface 314.

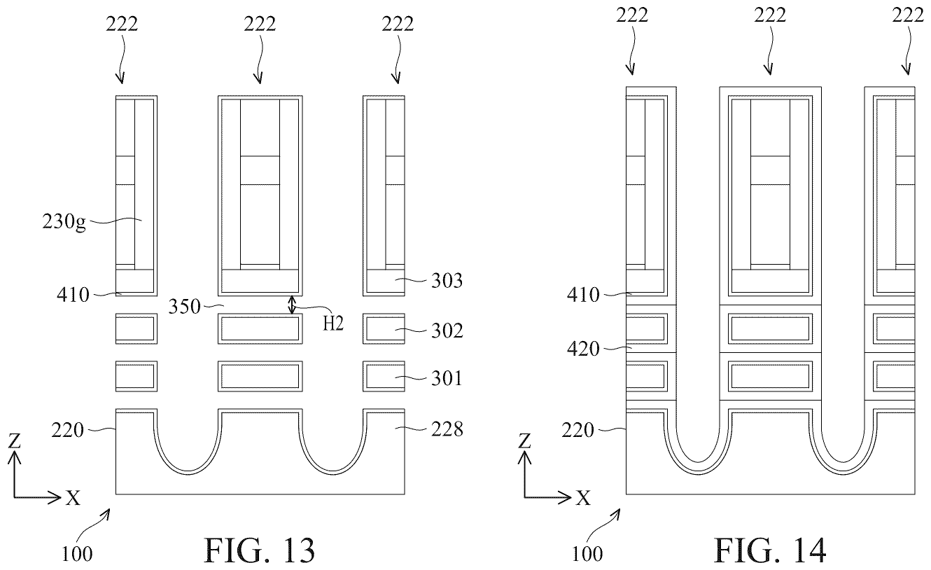

Method 1000 may continue, at operation S1090, with forming a barrier liner 410 over the structure of the partially fabricated device 100, as shown in FIG. 13, which is an X-cut cross-sectional view of a next stage of fabrication, along a single fin 220 and across a central sacrificial gate structure 222 between illustrated portions of two adjacent sacrificial gate structures 222.

As shown in FIG. 13, the barrier liner 410 covers each uppermost surface 311, each lowest surface 312, each end surface 313, and each end surface 314 of nanosheets 300 and mesa portion 228. Thus, all exposed surfaces of the fins 220 may be covered by the barrier liner 410. The barrier liner 410 may further cover the gate sidewall spacers 230g. In certain embodiments, the barrier liner 410 is blanket deposited in an isotropic process. The barrier liner 410 may be formed from any suitable material. The material forming the barrier liner 410 may be selected to minimize expansion during a subsequent process. For example, the material forming the barrier liner 410 may be unaffected by a subsequent process, such as by an oxidation process like a thermal oxidation process. As shown in FIG. 13, the barrier liner 410 does not fill the voids 350.

Method 1000 may continue, at operation S1100, with forming an interposer material 420 over the barrier liner 410, as shown in FIG. 14. FIG. 14 is, similar to FIG. 13, an X-cut cross-sectional view of a next stage of fabrication, along a single fin 220 and across a central sacrificial gate structure 222 between illustrated portions of two adjacent sacrificial gate structures 222.

As shown in FIG. 14, the interposer material 420 covers the barrier liner 410 over each uppermost surface 311, each lowest surface 312, each end surface 313, and each end surface 314 of nanosheets 300 and mesa portion 228 and over the gate sidewall spacers 230g. In certain embodiments, the interposer material 420 fills the voids 350, such that interposer material 420 merges, such as from an uppermost surface 311 to a lowest surface 312.

In certain embodiments, the interposer material 420 is blanket deposited in an isotropic process. The interposer material 420 may be formed from any suitable material. The interposer material 420 may be selected to provide a desired expansion during a subsequent process. For example, the interposer material 420 may be selected based on a response to an oxidation process. In certain embodiments, the interposer material 420 is silicon (Si) or silicon germanium (SiGe).

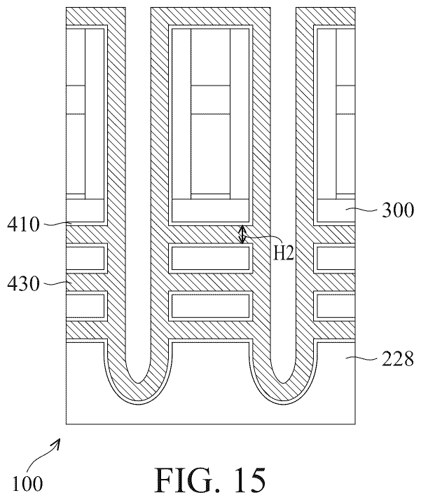

Referring to FIG. 15, the subsequent process is performed. Specifically, method 1000 may include, at operation S1110, performing a treatment to cause the interposer material 410 to expand and apply stress to the nanosheets 300 (301-303). For example, an oxidation process may be performed to convert the interposer material 420 to an oxidized material.

In other words, the interposer material 420 is converted to a treated interposer material 430, such as an oxidized interposer material 430. In certain embodiments, the barrier liner 410 remains located between the treated interposer material 430 and the semiconductor material of the nanosheets 300 and of the mesa portion 228 of the fins 220.

As shown, in non-confined regions, the treated interposer material 430 grows to a greater thickness than the original interposer material 420. In the confined regions of the voids 350 an increase in thickness is limited by the barrier liner 410 on the nanosheets 300 or mesa portion 228. As a result, a compressive stress force is applied to the nanosheets 300 and mesa portion 228 by the treated interposer material 430. Thus, the nanosheets 300 and mesa portion 228 are strained.

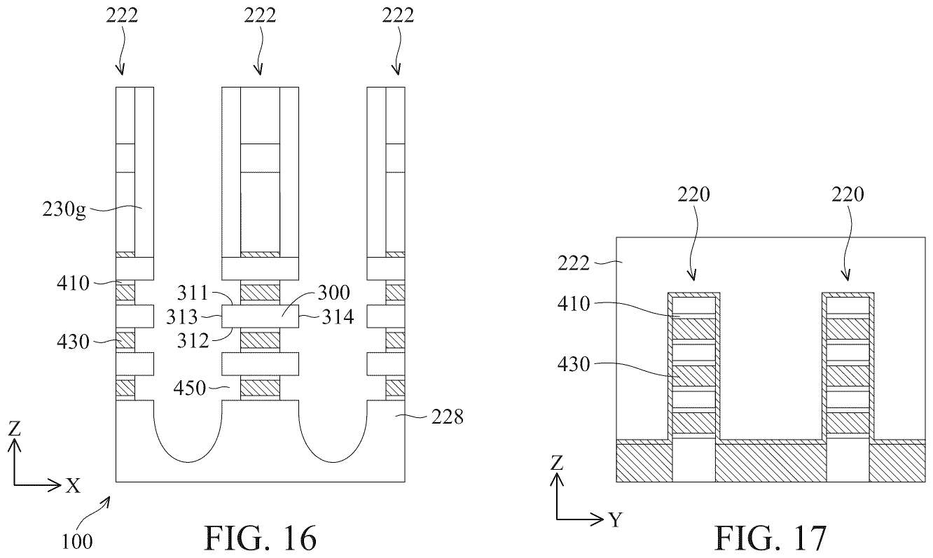

Referring to FIG. 16, method 1000 may include, at operation S1120, recessing the treated interposer material 430. FIG. 16 is an X-cut cross-sectional view of a next stage of fabrication, along a single fin 220 and across a central sacrificial gate structure 222 between illustrated portions of two adjacent sacrificial gate structures 222. FIG. 17 is a Y-cut cross-sectional view of the stage of fabrication of FIG. 16, along sacrificial gate 222 and across two fins 220.

Cross-referencing FIGS. 16 and 17, the treated interposer material 430 may be removed from the gate sidewall spacers 230g, from the end surfaces 313 of nanosheets 300 and mesa portion 228, from the end surfaces 314 of nanosheets 300 and mesa portion 228, from portions of uppermost surfaces 311, and from portions of lowest surfaces 312. Specifically, the treated interposer material 430 and barrier liner 410 may be laterally etched to form recesses 450 between the uppermost surfaces 311 and lowest surfaces 312.

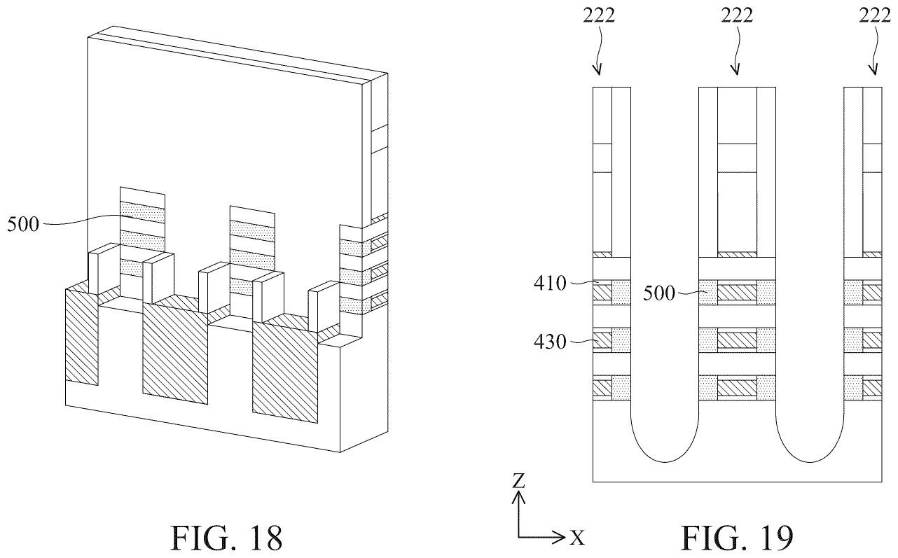

Referring to FIG. 18, method 1000 may include, at operation S1130, forming inner spacers 500. FIG. 19 is an X-cut cross-sectional view of the stage of fabrication of FIG. 18, along a single fin 220 and across a central sacrificial gate structure 222 between illustrated portions of two adjacent sacrificial gate structures 222.

Cross-referencing FIGS. 18 and 19, the inner spacers 500 are formed in the recesses 450 adjacent to the remaining treated interposer material 430 and barrier liner 410. In certain embodiments, the inner spacers 500 may be formed from silicon oxides, silicon nitrides, silicon carbides, silicon carbide nitride, silicon oxide carbide, silicon carbide oxynitride, and/or other suitable dielectric materials. The inner spacers 500 may be formed by atomic layer deposition (ALD) or any other suitable method. As shown, after deposited the material forming inner spacers 500, the material may be trimmed from the ends of nanosheets 300.

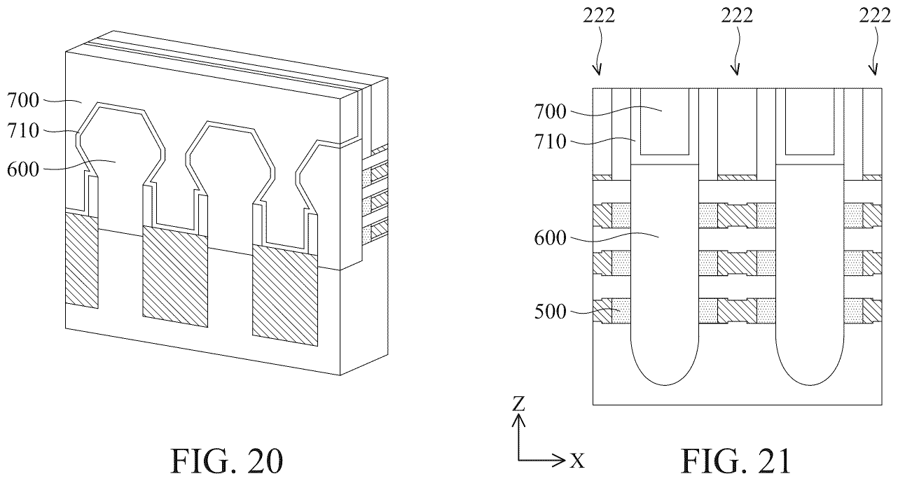

At FIG. 20, method 1000 further includes forming source/drain features 600 at operation S1140 Further, method 1000 may include forming an interlayer dielectric (ILD) material 700 at operation S1150.

FIG. 21 is an X-cut cross-sectional view of the stage of fabrication of FIG. 20, along a single fin 220 and across a central sacrificial gate structure 222 between illustrated portions of two adjacent sacrificial gate structures 222.

Cross-referencing FIGS. 20 and 21, the source/drain features 600 are formed over the fins 220 and between the inner spacers 500. The source/drain features 600 may be epitaxially grown. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

Further, the interlayer dielectric (ILD) material 700 is formed over the source/drain features 600. As shown, an etch stop layer 710 may be formed over the source/drain features 600 before the interlayer dielectric (ILD) material 700 is formed.

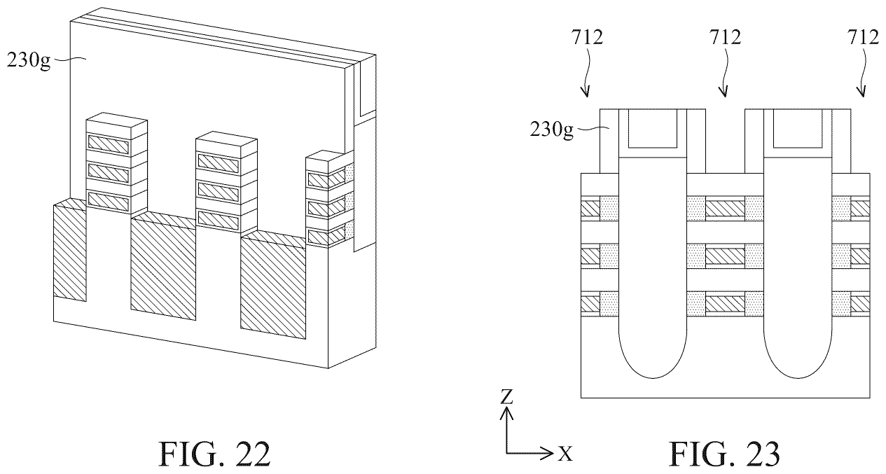

At FIG. 22, method 1000 further includes removing the sacrificial gate structures 222 at operation S1160 to form gate cavities 712. FIG. 23 is an X-cut cross-sectional view of the stage of fabrication of FIG. 22, along a single fin 220 and across a central gate cavity 712 between illustrated portions of two adjacent gate cavities 712. As shown, the gate sidewall spacers 230g bound the gate cavity 712.

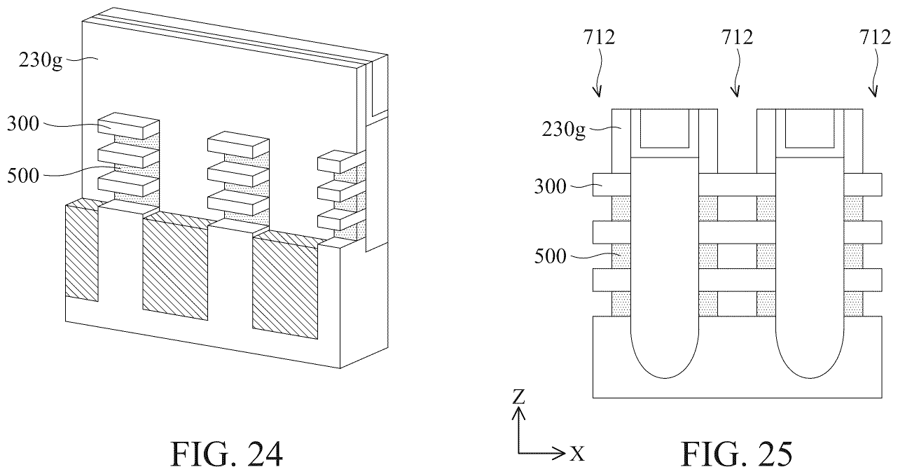

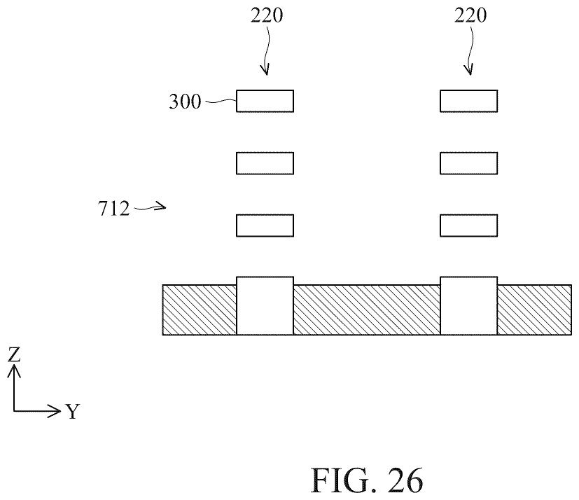

At FIG. 24, method 1000 further includes removing the remaining portions of the treated interposer material 430 and barrier layer 410, at operation S1170. FIG. 25 is an X-cut cross-sectional view of the stage of fabrication of FIG. 24, along a single fin 220 and across a central gate cavity 712 between illustrated portions of two adjacent gate cavities 712. FIG. 26 is a Y-cut cross-sectional view of the stage of fabrication of FIG. 24, along a single gate cavity 712 and across two fins 220.

Cross-referencing FIGS. 24-26, after the treated interposer material 430 and barrier layer 410 are removed, the gate cavities 712 extend downward and around the nanosheets 300 and are bound in the X-direction by the inner spacers 500.

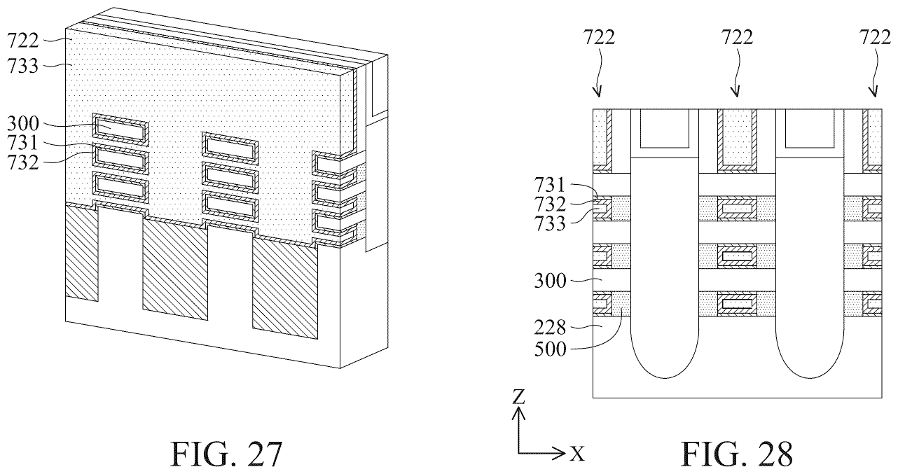

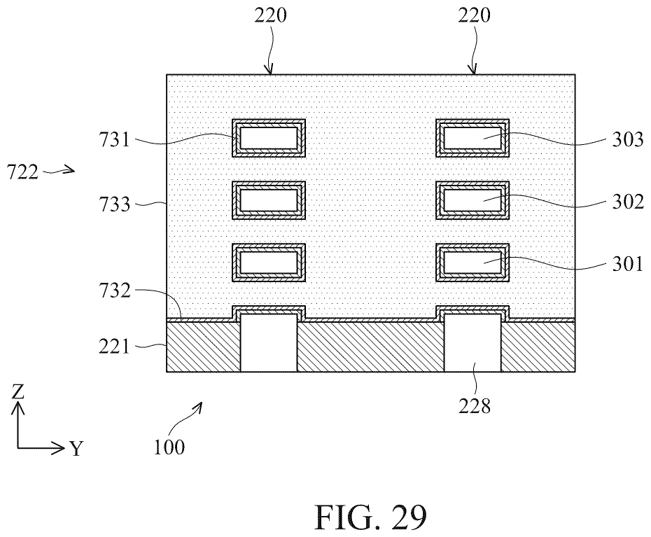

At FIG. 27, method 1000 further includes forming a gate 722 in the gate cavity 712, at operation S1180. FIG. 28 is an X-cut cross-sectional view of the stage of fabrication of FIG. 27, along a single fin 220 and across a central gate 722 between illustrated portions of two gates 722. FIG. 29 is a Y-cut cross-sectional view of the stage of fabrication of FIG. 24, along a single gate 722 and across two fins 220.

Cross-referencing FIGS. 27-29, the gate 722 may be formed according to a replacement metal gate process. In certain embodiments, the replacement metal gate process includes forming an interfacial layer 731 on the uppermost surfaces 311 and lowest surfaces 312. The interfacial layer 731 may include a silicon oxide (SiO₂) layer. Alternatively, the interfacial layer 731 may optionally include HfSiO or SiON. The interfacial layer 731 may be formed by atomic layer deposition (ALD), chemical vapor deposition (CVD), thermal oxidation, wet oxidation, radical oxidation (RadOx) or combinations thereof. In certain embodiments, the interfacial layer 731 is selectively formed on the semiconductor material of the nanosheets 300 and mesa portion 228, and is not formed on the inner spacers 500.

In certain embodiments, the replacement metal gate process includes forming a dielectric layer 732 over the interfacial layer 731. In accordance with some embodiments, the gate dielectric layer(s) 732 comprises silicon oxide, silicon nitride, or multilayers thereof. In some embodiments, the gate dielectric layer(s) 732 is a high-k dielectric material, and in these embodiments, the gate dielectric layer(s) 732 may have a k value greater than about 7.0, and may include a metal oxide or a silicate of Hf, Al, Zr, La, Mg, Ba, Ti, Pb, and combinations thereof. The formation methods of the gate dielectric layer(s) 732 may include Molecular-Beam Deposition (MBD), ALD, CVD, PECVD, metal organic CVD (MOCVD), PVD, thermal oxidation, combinations thereof, or other suitable techniques.

In certain embodiments, the gate dielectric layer(s) 732 are formed on the interfacial layer 731 overlying the semiconductor material of the nanosheets 300 and mesa portion 228, as well as on the inner spacers 500 and on the shallow trench isolation (STI) features 221.

In certain embodiments, the replacement metal gate process includes forming a gate electrode material 733 over the gate dielectric layer 732 to fill the gate cavities 712. The gate electrode material 733 is deposited over the gate dielectric layer(s) 732 and fills the remaining portion of the gate cavity 712. The gate electrode material 733 may be a metal-containing material such as TiN, TaN, TaC, Co, Ru, Al, combinations thereof, or multi-layers thereof. For example, although a single gate electrode material is illustrated, any number of work function tuning layers may be deposited.

After completing the replacement metal gate process, each semiconductor nanosheet 300 is wrapped in gate dielectric 732 and surrounded by gate electrode material 733.

Method 1000 may continue at operation S1190 where further processing may be performed. Generally, the further processing may form various features and regions known in the art. For example, subsequent processing may form contact openings, contact metal, as well as various contacts/vias/lines and multilayer interconnect features (e.g., metal layers and interlayer dielectrics) over the substrate 202, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after method 1000, and some process steps described above may be replaced or eliminated in accordance with various embodiments of method 1000.

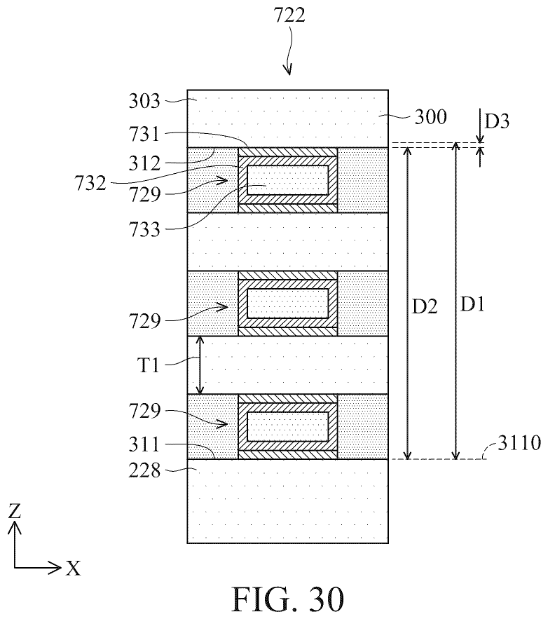

Method 1000 may result in a device 100 having certain characteristics. For example referring to FIG. 30, the channel region of a fin 220 and gate 722 is illustrated. FIG. 30 is a focused view of a portion of FIG. 28.

In certain embodiments, the method provides nanosheets having a reduced height difference due to reduced etching or no etching of top surfaces or bottom surfaces of the nanosheets during processing. For example, the uppermost nanosheet channel 303 has a lowest or bottom surface 312 with a reduced height difference.

For example, as shown in FIG. 30, the uppermost surface 311 of the mesa portion 228 defines a lateral plane 3110 perpendicular to a vertical Z-direction. Under-sheet portions 729 of the gate structure 722 are located between the mesa portion 228 and the uppermost semiconductor nanosheet channel 303 of the fin structure 220. The uppermost semiconductor nanosheet channel 303 has a lowest or bottom surface 312 that has a highest point at a greatest vertical distance D1 from the lateral plane 3110 and a lowest point at a shortest vertical distance D2 from the lateral plane 3110. A difference D3 between the greatest vertical distance D1 and shortest vertical distance D2 is less than three nanometers. For example, difference D3 may be zero, or may be at least 0.05 nanometers, such as at least 0.1, at least 0.2, at least 0.3, at least 0.4, at least 0.5, at least 0.6, at least 0.7, at least 0.8, at least 0.9, at least 1, at least 1.1, at least 1.2, at least 1.3, at least 1.4, at least 1.5, at least 1.6, at least 1.7, at least 1.8, at least 1.9, at least 2.0, at least 2.1, at least 2.2, at least 2.3, at least 2.4, at least 2.5, at least 2.6, at least 2.7, at least 2.8, or at least 2.9 nanometers. Difference D3 may be less than 3 nanometers, such as less than 2.9, less than 2.8, less than 2.7, less than 2.6, less than 2.5, less than 2.4, less than 2.3, less than 2.2, less than 2.1, less than 2.0, less than 1.9, less than 1.8, less than 1.7, less than 1.6, less than 1.5, less than 1.4, less than 1.3, less than 1.2, less than 1.1, less than 1.0, less than 0.9, less than 0.8, less than 0.7, less than 0.6, less than 0.5, less than 0.4, less than 0.3, less than 0.2, or less than 0.1 nanometers.

In certain embodiments, each uppermost surface 311 is planar and each lowest surface 312 is planar.

In certain embodiments, each semiconductor nanosheet channel 300 has a vertical thickness or height T1, from uppermost surface 311 to lowest surface 312, of from three to eight nanometers. For example, each vertical thickness T1 may be at least 3.0, such as at least 3.5, at least 4, at least 4.5, at least 5, at least 5.5, at least 6, at least 6.5, at least 7, or at least 7.5 nanometers. Further, each vertical thickness T1 may be no more than 8.0 nanometers, such as no more than 7.5, no more than 7, no more than 6.5, no more than 6, no more than 5.5, no more than 5, no more than 4.5, no more than 4, no more than 3.5, or no more than 3 nanometers.

In the embodiments of FIGS. 2-30, the amount of stress applied by the treated interposer material is less than would be applied had the interposer material 420 filled the volume between each pair of adjacent nanosheets 300. The nanosheets 300 are separated by a vertical distance or height H1. As a result, when the layers 214 are removed, the void 350 has the same vertical distance or height H1. Adding the barrier liner 410 reduces the height of the void 350 to a reduced height H2, as shown in FIG. 13. Therefore, at operation S1100, the amount of interposer material 420 that may be added to fill the void 350 is limited by the reduced height H2. In other words, the volume of the interposer material 420 is limited in the Z-direction. With a reduced amount of interposer material 420, the amount of stress applied by the treatment of the interposer material 420 is also reduced.

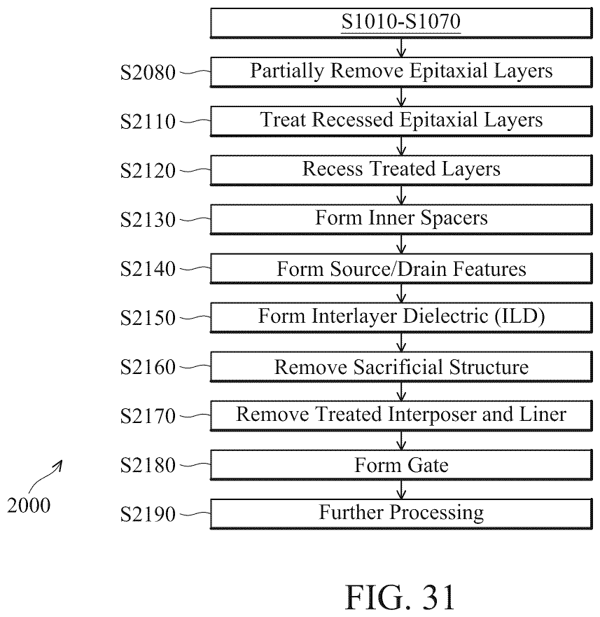

In the embodiments of FIGS. 31-45, the amount of stress applied by the treated interposer material is also less than would be applied if the interposer material 420 filled the volume between each pair of adjacent nanosheets 300. However, in the embodiments of FIGS. 31-45, the volume is limited in the X-direction, rather than in the Z-direction as in FIGS. 2-30.

FIG. 31 is a flow chart of a method 2000 of fabrication of a semiconductor device 100 (such as a multi-gate device), in accordance with various embodiments. Method 2000 is discussed below with reference to a GAA device having a channel region that may be referred to as a nanosheet or nanosheet channel and which may include various geometries (e.g., cylindrical, bar-shaped) and dimensions. However, it will be understood that aspects of method 2000 may be equally applied to other types of multi-gate devices without departing from the scope of the present disclosure. In some embodiments, method 2000 may be used to fabricate the multi-gate device 100, described above with reference to FIG. 1. Thus, one or more aspects discussed above with reference to the multi-gate device 100 may also apply to method 2000. It is understood that method 2000 includes steps having features of a complementary metal-oxide-semiconductor (CMOS) technology process flow and thus, are only described briefly herein. Also, additional steps may be performed before, after, and/or during method 2000.

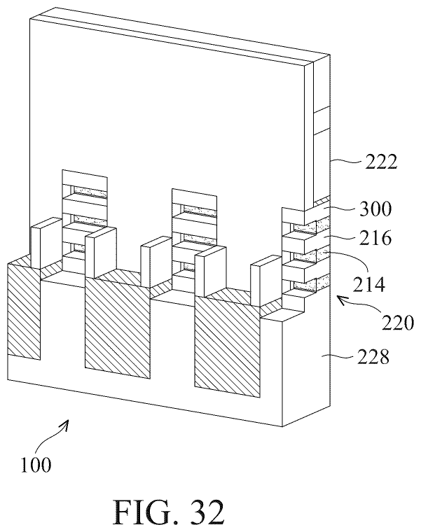

Method 2000 is described below with reference to FIGS. 32-45, which provide perspective views of the multi-gate device 100 and cross-sectional views of the multi-gate device 100 along a plane substantially parallel to a plane defined by the X and Z axes in FIG. 1, as described, illustrating various stages of fabrication according to method 2000.

Further, the semiconductor device 100 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the concepts of the present disclosure. In some embodiments, the semiconductor device 100 includes a plurality of semiconductor devices (e.g., transistors), including PFETs, NFETs, etc., which may be interconnected. Moreover, it is noted that the process steps of method 2000, including any descriptions given with reference to the figures are merely exemplary and are not intended to be limiting beyond what is specifically recited in the claims that follow.

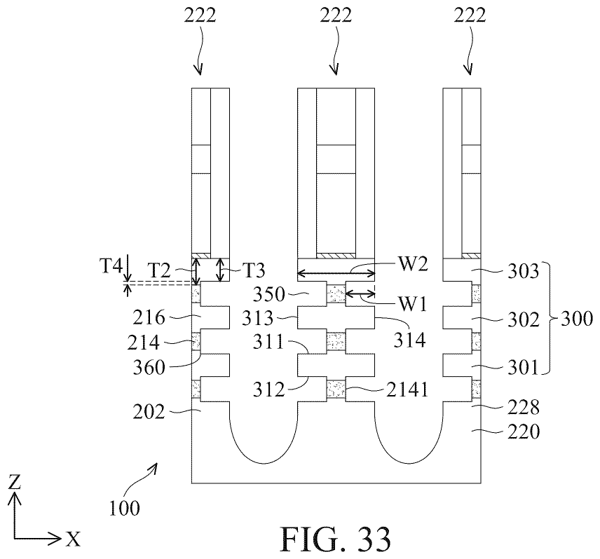

Method 2000 includes operations S1010 to S1070, as described above. After removing portions 220a of the fins 220 adjacent to and not covered by the sacrificial gate structure 222 (e.g., source/drain regions) at operation S1070 and as shown in FIGS. 8-9, method 2000 includes, at operation S2080, removing only a portion of the epitaxial layers 214, i.e., the silicon germanium (SiGe) layers 214, as shown in FIG. 32. FIG. 33 is an X-cut cross-sectional view of the stage of fabrication of FIG. 32, along a single fin 220 and across a central sacrificial gate structure 222 between illustrated portions of two adjacent sacrificial gate structures 222.

Cross-referencing FIGS. 32 and 33, after removal of portions of the layers 214, each layer 214 is recessed to a laterally recessed surface 2141. In an embodiment in which the layers 214 are formed of silicon germanium (SiGe) and the layers 216 are formed of silicon (Si), the layers 214 may be recessed, for example, by an NMOS SiGe removal process. In some embodiments, the removal process may use an etchant that etches the silicon germanium at a higher rate than the silicon, such as NH₄OH:H₂O₂:H₂O (ammonia peroxide mixture, APM), H₂SO₄+H₂O₂ (sulfuric acid peroxide mixture, SPM), or the like. Other suitable processes and materials may be used. This etching process removes a lateral portion of the layers 214 to form recesses 350 at each recessed surface 2141.

As shown, the portion of the layers 216 adjacent to the recesses 350 may be etched in the Z-direction. For example, the portions of the layers 216 covered by the non-recessed portion of the layers 214 have an original vertical thickness T2. The portions of the layers 216 not-covered by the non-recessed portion of the layers 214, i.e., adjacent to recesses 350, have a reduced vertical thickness T3. Each surface 311 and 312 adjacent to a recess 350 may have a height differential of T4. Each surface 311 and 312 is formed with a shoulder 360 where the thickness T3 and thickness T4 meet.

The laterally recessed surface 2141 of the layers 214 may be distanced from the original ends 313 or 314, respectively, by a lateral distance or width W1. Therefore, the recesses 350 may have a lateral width W1 in the X-direction.

As shown, the nanosheets 300 (and the layers 214 before recessing) have a lateral width W2 in the X-direction.

In certain embodiments the ratio of width W1 to width W2 is from 1:100 to 49:100. For example, the W1:W2 ratio may be at least 1:100, 2:100, 5:100, 10:100, 15:100, 20:100, 25:100, 30:100, 35:100, 40:100, or 45:100. Further, the W1:W2 ratio may be no more than 49:100, 45:100, 40:100, 35:100, 30:100, 25:100, 20:100, 15:100, 10:100, 5:100, or 2:100.

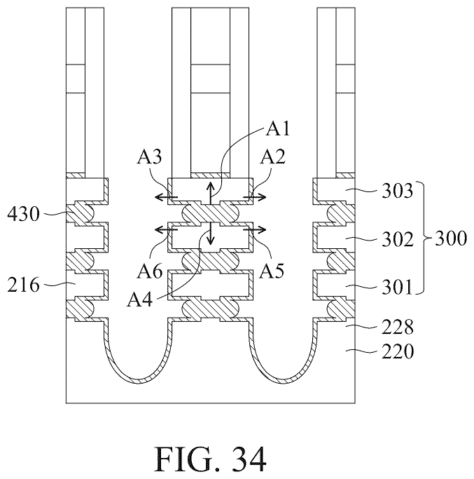

Referring to FIG. 34, method 2000 may include, at operation S1110, performing a treatment to cause the recessed layers 214 to expand and apply stress to the nanosheets 300 (301-303). FIG. 34 is an X-cut cross-sectional view of a next stage of fabrication, along a single fin 220 and across a central sacrificial gate structure 222 between illustrated portions of two adjacent sacrificial gate structures 222. The treatment may be an oxidation process performed to convert the layer 214 to an oxidized material. As shown, the oxidation process may also oxidize portions of layers 216.

In other words, the recessed layers 214 are converted to a treated interposer material 430, such as an oxidized interposer material 430. As shown, in non-confined directions, i.e., laterally, the treated interposer material 430 grows to a greater thickness than the original recessed layers 214. In the confined vertical direction of the recesses 350, an increase in thickness in the Z-direction is limited by the layers 216 (or nanosheets 300) or mesa portion 228. As a result, a compressive stress force is applied to the nanosheets 300 and mesa portion 228 by the treated interposer material 430. Thus, the nanosheets 300 and mesa portion 228 are strained.

Specifically, with reference to a single segment of treated interposer material 430, the uppermost nanosheet 303 is strained in the vertical direction as indicated by arrow A1, and in the lateral directions indicated by arrows A2 and A3. Likewise, the intermediate nanosheet 302 is strained in the vertical direction as indicated by arrow A4 and in the lateral directions indicated by arrows A5 and A6. Due to the interposer volume expansion, extra strain is applied and n-mobility is increased.

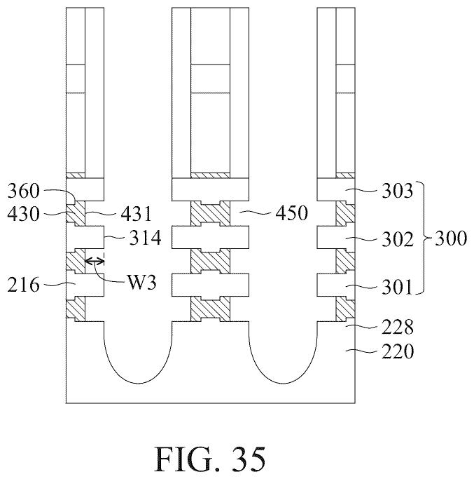

Referring to FIG. 35, method 2000 may include, at operation S1120, recessing the treated interposer material 430. FIG. 35 is an X-cut cross-sectional view of a next stage of fabrication, along a single fin 220 and across a central sacrificial gate structure 222 between illustrated portions of two adjacent sacrificial gate structures 222.

In FIG. 35, the treated interposer material 430 is laterally recessed to a recessed surface 431 to form recesses 450. In certain embodiments, the recessed surface 431 is located between the shoulder 360 and the nearest respective end 313 or 314. In other words, the lateral width W3 of the recess 450 is less than the lateral width W1 of the recess 350 (see FIG. 33).

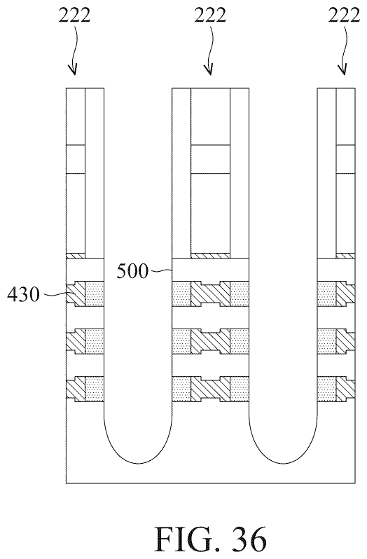

Referring to FIG. 36, method 2000 may include, at operation S2130, forming inner spacers 500. FIG. 36 is an X-cut cross-sectional view of the next stage of fabrication, along a single fin 220 and across a central sacrificial gate structure 222 between illustrated portions of two adjacent sacrificial gate structures 222.

As shown in FIG. 36, the inner spacers 500 are formed in the recesses 450 adjacent to the remaining treated interposer material 430. In certain embodiments, the inner spacers 500 may be formed from silicon oxides, silicon nitrides, silicon carbides, silicon carbide nitride, silicon oxide carbide, silicon carbide oxynitride, and/or other suitable dielectric materials. The inner spacers 500 may be formed by atomic layer deposition (ALD) or any other suitable method. As shown, after deposited the material forming inner spacers 500, the material may be trimmed from the ends of nanosheets 300.

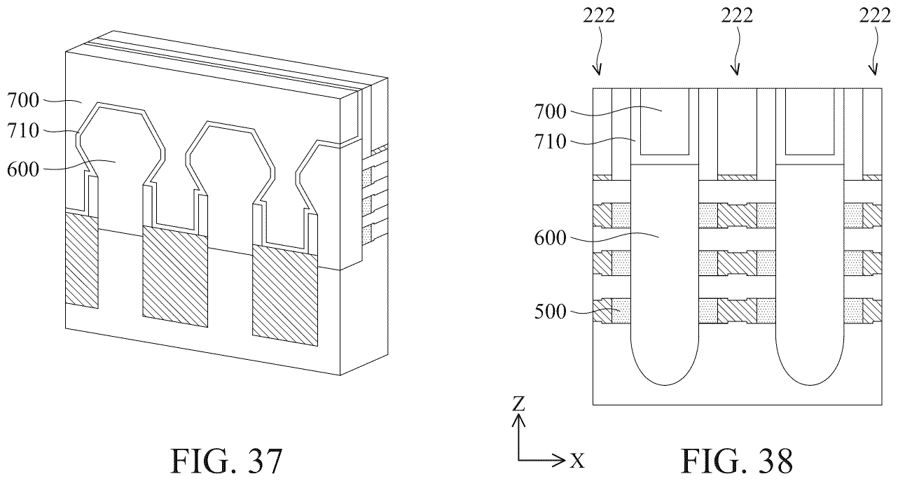

FIG. 37 is a perspective view of device 100 illustrating that method 2000 further includes forming source/drain features 600 at operation S1140 Further, method 2000 may include forming an interlayer dielectric (ILD) material 700 at operation S1150.

FIG. 38 is an X-cut cross-sectional view of the stage of fabrication of FIG. 37, along a single fin 220 and across a central sacrificial gate structure 222 between illustrated portions of two adjacent sacrificial gate structures 222.

Cross-referencing FIGS. 37 and 38, the source/drain features 600 are formed over the fins 220 and between the inner spacers 500. The source/drain features 600 may be epitaxially grown. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

Further, the interlayer dielectric (ILD) material 700 is formed over the source/drain features 600. As shown, an etch stop layer 710 may be formed over the source/drain features 600 before the interlayer dielectric (ILD) material 700 is formed.

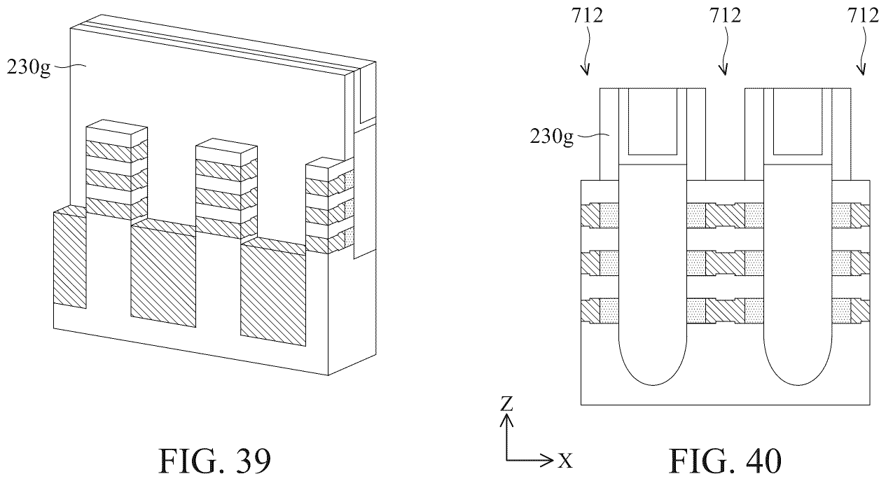

At FIG. 39, method 2000 further includes removing the sacrificial gate structures 222 at operation S1160 to form gate cavities 712. FIG. 40 is an X-cut cross-sectional view of the stage of fabrication of FIG. 39, along a single fin 220 and across a central gate cavity 712 between illustrated portions of two adjacent gate cavities 712. As shown, the gate sidewall spacers 230g bound the gate cavity 712.

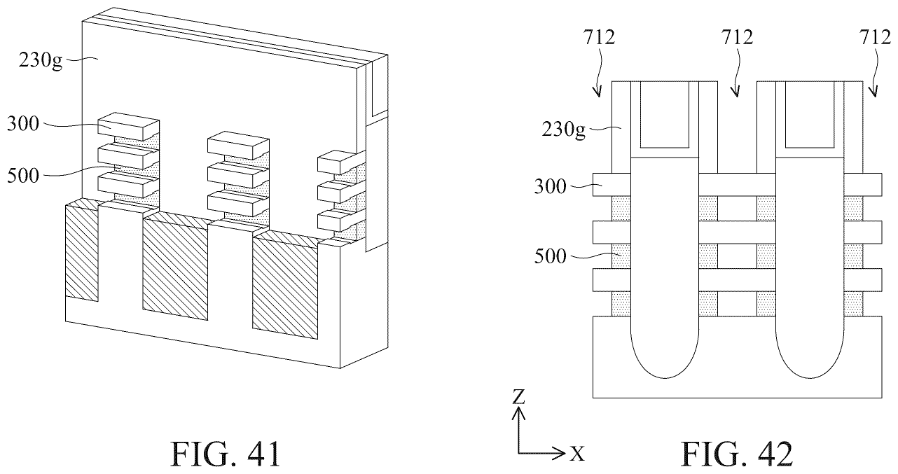

At FIG. 41, method 2000 further includes removing the remaining portions of the treated interposer material 430 and barrier layer 410, at operation S1170. FIG. 42 is an X-cut cross-sectional view of the stage of fabrication of FIG. 41, along a single fin 220 and across a central gate cavity 712 between illustrated portions of two adjacent gate cavities 712.

Cross-referencing FIGS. 41-42, after the treated interposer material 430 and barrier layer 410 are removed, the gate cavities 712 extend downward and around the nanosheets 300 and are bound in the X-direction by the inner spacers 500.

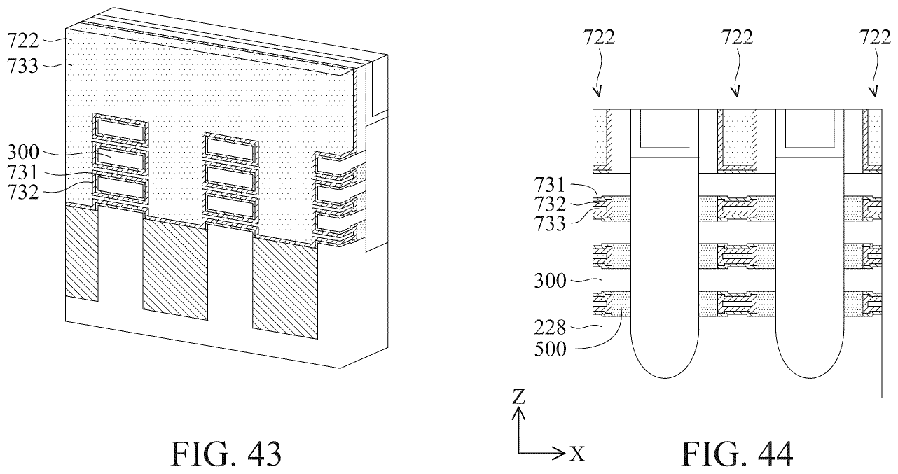

At FIG. 43, method 2000 further includes forming a gate 722 in the gate cavity 712, at operation S1180. FIG. 44 is an X-cut cross-sectional view of the stage of fabrication of FIG. 43, along a single fin 220 and across a central gate 722 between illustrated portions of two gates 722.

Cross-referencing FIGS. 43-44, the gate 722 may be formed according to a replacement metal gate process. In certain embodiments, the replacement metal gate process includes forming an interfacial layer 731 on the uppermost surfaces 311 and lowest surfaces 312. The interfacial layer 731 may include a silicon oxide (SiO₂) layer. Alternatively, the interfacial layer 731 may optionally include HfSiO or SiON. The interfacial layer 731 may be formed by atomic layer deposition (ALD), chemical vapor deposition (CVD), thermal oxidation, wet oxidation, radical oxidation (RadOx) or combinations thereof. In certain embodiments, the interfacial layer 731 is selectively formed on the semiconductor material of the nanosheets 300 and mesa portion 228, and is not formed on the inner spacers 500.

In certain embodiments, the replacement metal gate process includes forming a dielectric layer 732 over the interfacial layer 731. In accordance with some embodiments, the gate dielectric layer(s) 732 comprises silicon oxide, silicon nitride, or multilayers thereof. In some embodiments, the gate dielectric layer(s) 732 is a high-k dielectric material, and in these embodiments, the gate dielectric layer(s) 732 may have a k value greater than about 7.0, and may include a metal oxide or a silicate of Hf, Al, Zr, La, Mg, Ba, Ti, Pb, and combinations thereof. The formation methods of the gate dielectric layer(s) 732 may include Molecular-Beam Deposition (MBD), ALD, CVD, PECVD, metal organic CVD (MOCVD), PVD, thermal oxidation, combinations thereof, or other suitable techniques.

In certain embodiments, the gate dielectric layer(s) 732 are formed on the interfacial layer 731 overlying the semiconductor material of the nanosheets 300 and mesa portion 228, as well as on the inner spacers 500 and on the shallow trench isolation (STI) features 221.

In certain embodiments, the replacement metal gate process includes forming a gate electrode material 733 over the gate dielectric layer 732 to fill the gate cavities 712. The gate electrode material 733 is deposited over the gate dielectric layer(s) 732 and fills the remaining portion of the gate cavity 712. The gate electrode material 733 may be a metal-containing material such as TiN, TaN, TaC, Co, Ru, Al, combinations thereof, or multi-layers thereof. For example, although a single gate electrode material is illustrated, any number of work function tuning layers may be deposited.

After completing the replacement metal gate process, each semiconductor nanosheet 300 is wrapped in gate dielectric 732 and surrounded by gate electrode material 733.

Method 2000 may continue at operation S1190 where further processing may be performed. Generally, the further processing may form various features and regions known in the art. For example, subsequent processing may form contact openings, contact metal, as well as various contacts/vias/lines and multilayer interconnect features (e.g., metal layers and interlayer dielectrics) over the substrate 202, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after method 2000, and some process steps described above may be replaced or eliminated in accordance with various embodiments of method 2000.

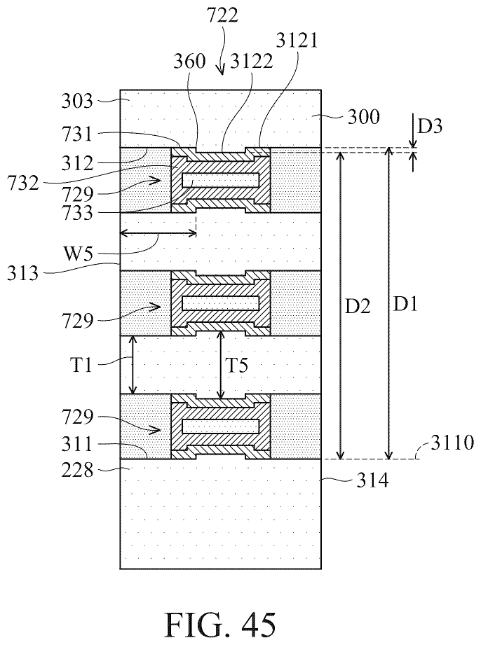

Method 2000 may result in a device 100 having certain characteristics. For example referring to FIG. 45, the channel region of a fin 220 and gate 722 is illustrated. FIG. 45 is a focused view of a portion of FIG. 44.

In certain embodiments, the method provides nanosheets having a reduced height difference due to reduced etching or no etching of top surfaces or bottom surfaces of the nanosheets during processing. For example, the uppermost nanosheet channel 303 has a lowest or bottom surface 312 with a reduced height difference.

For example, as shown in FIG. 45, the uppermost surface 311 of the mesa portion 228 at the ends 313 and 314 defines a lateral plane 3110 perpendicular to a vertical Z-direction. Under-sheet portions 729 of the gate structure 722 are located between the mesa portion 228 and the uppermost semiconductor nanosheet channel 303 of the fin structure 220. The uppermost semiconductor nanosheet channel 303 has a lowest or bottom surface 312 that has a highest point 3121 at a greatest vertical distance D1 from the lateral plane 3110 and a lowest point 3122 at a shortest vertical distance D2 from the lateral plane 3110. A difference D3 between the greatest vertical distance D1 and shortest vertical distance D2 is less than three nanometers. For example, difference D3 may be zero, or may be at least 0.05 nanometers, such as at least 0.1, at least 0.2, at least 0.3, at least 0.4, at least 0.5, at least 0.6, at least 0.7, at least 0.8, at least 0.9, at least 1, at least 1.1, at least 1.2, at least 1.3, at least 1.4, at least 1.5, at least 1.6, at least 1.7, at least 1.8, at least 1.9, at least 2.0, at least 2.1, at least 2.2, at least 2.3, at least 2.4, at least 2.5, at least 2.6, at least 2.7, at least 2.8, or at least 2.9 nanometers. Difference D3 may be less than 3 nanometers, such as less than 2.9, less than 2.8, less than 2.7, less than 2.6, less than 2.5, less than 2.4, less than 2.3, less than 2.2, less than 2.1, less than 2.0, less than 1.9, less than 1.8, less than 1.7, less than 1.6, less than 1.5, less than 1.4, less than 1.3, less than 1.2, less than 1.1, less than 1.0, less than 0.9, less than 0.8, less than 0.7, less than 0.6, less than 0.5, less than 0.4, less than 0.3, less than 0.2, or less than 0.1 nanometers.

In certain embodiments, each semiconductor nanosheet channel 300 has outer terminal regions adjacent ends 313 and 314 that have a vertical thickness or height T1, from uppermost surface 311 to lowest surface 312, of from three to eight nanometers. For example, each vertical thickness T1 may be at least 3.0, such as at least 3.5, at least 4, at least 4.5, at least 5, at least 5.5, at least 6, at least 6.5, at least 7, or at least 7.5 nanometers. Further, each vertical thickness T1 may be no more than 8.0 nanometers, such as no more than 7.5, no more than 7, no more than 6.5, no more than 6, no more than 5.5, no more than 5, no more than 4.5, no more than 4, no more than 3.5, or no more than 3 nanometers.

As further shown, each semiconductor nanosheet channel 300 an inner region, from shoulder 360 to shoulder 360, that have an increased vertical thickness or height T5, from uppermost surface 311 to lowest surface 312. Vertical thickness T5 may be 6 nanometers greater than vertical thickness T1, i.e., each shoulder 360 may have a vertical length of 3 nanometers. For example, each vertical thickness T5 may be at least 0.5, such as at least 1, at least 1.5, at least 2, or at least 2.5, at least 3, at least 3.5, at least 4, at least 4.5, at least 5, at least 5.5 nanometers greater than vertical thickness T1. Further, each vertical thickness T5 may be no more than 6 nanometers, such as no more than 5.5, 5, 4.5, 4, 3.5, 3, 2.5, 2, 1.5, 1, or 0.5 nanometers greater than vertical thickness T1.

As shown in FIG. 45, each shoulder 360, i.e., interface between terminal and central regions, is located at a lateral distance or width W5 in the X-direction from the end 313. In certain embodiments, width W5 is from six to twelve nanometers. For example width W5 may be at least 6, such as at least 6.5, at least 7, at least 7.5, at least 8, at least 8.5, at least 9, at least 9.5, at least 10, at least 10.5, at least 11, or at least 11.5 nanometers. Further, W5 may be at most 12, such as at most 11.5, at most 11, at most 10.5, at most 10, at most 9.5, at most 9, at most 8.5, at most 8, at most 7.5, at most 7, or at most 6.5 nanometers.

In the embodiments of FIGS. 31-45, the amount of stress applied by the treated interposer material is less than would be applied had the interposer material 420 filled the volume between each pair of adjacent nanosheets 300. As shown in FIG. 33, nanosheets 300 have a lateral length W2, and the recessed layer 214 has a lateral width equal to the difference of width W2 and double the recess width W1 (W2−2(W1)). Thus, the volume of each recessed layer 214 is less than the original volume of each layer 214. Specifically, the lateral width of each recessed layer 214 is less than the original width of each layer 214. In other words, the volume of the second layer 216 converted to interposer material 430 is limited in the X-direction. With a reduced amount of layer 216, the amount of stress applied by the treatment of the layer is also reduced to a desired amount.

In embodiments herein, negative effects caused by the presence of germanium in layers 214 are avoided. Specifically, when germanium in layers 214 is present after formation of source/drain features 600, thermal processing may cause diffusion of germanium from the layers 214 to phosphorus-doped silicon n-type source/drain features 600 and may enhance diffusion of phosphorus from the source/drain features 600 to the sacrificial layer 214. As a result, n-type mobility may be reduced. To avoid such negative effects herein, in certain embodiments the layers 214 are removed and are replaced with interposer layers 430. The interposer layers 430 may block diffusion.

Thus, one of the embodiments of the present disclosure describes a method includes forming a fin including a first material lying over a second material; forming a sacrificial gate over the fin, wherein a channel region of the fin including the first material and the second material lies directly under the sacrificial gate and between two non-channel regions of the fin including the first material and the second material; removing the non-channel regions of the fin; performing a process to replace the second material in the channel region of the fin with a third material; forming source/drain features in the non-channel regions; removing the sacrificial gate; removing the third material; and forming a gate over the fin.

In certain embodiments, the method further includes straining the first material with the third material to form a strained first material.

In certain embodiments of the method, performing the process to replace the second material with the third material includes: removing the second material; forming a third material precursor under the first material; and treating the third material precursor to form the third material.

In certain embodiments of the method, performing the process to replace the second material with the third material includes: removing the second material to form a void under a bottom surface of the first material; forming a liner on the bottom surface; and forming the third material under the liner.

In certain embodiments of the method, performing the process to replace the second material with the third material includes: removing a portion of the second material, wherein a remaining portion of the second material remains under the first material; and converting the remaining portion of the second material to the third material.

In certain embodiments of the method, after removing the portion of the second material, a covered surface portion of the first material is covered by the remaining portion of the second material and a non-covered surface portion of the first material is not covered by the remaining portion of the second material; converting the remaining portion of the second material to the third material includes performing an oxidation process; the oxidation process oxidizes the non-covered surface portion of the first material to form a first oxidized material; and the method further includes removing at least a portion of the first oxidized material and at least a portion of the third material before forming the source/drain features in the non-channel regions.

In certain embodiments of the method, the second material is silicon germanium (SiGe) and wherein the third material is free of germanium.

In certain embodiments of the method, the fin extends in a first direction; after removing the non-channel regions of the fin, the second material contacts the first material along an interface having a first length in the first direction; performing the process to replace the second material with the third material includes removing at least a portion of the second material; after performing the process to replace the second material with the third material, the third material in the channel region has a third width in the first direction; and the third width is less than the first length.

In certain embodiments of the method, the fin extends in a first direction; the first material is located over the second material in a second direction perpendicular to the first direction; before performing the process to replace the second material with the third material, the second material in the channel region has a second vertical thickness in the second direction; after performing the process to replace the second material with the third material, the third material in the channel region has a third vertical thickness in the second direction; and the third vertical thickness is less than the second vertical thickness.

In another embodiment, a method includes forming a first material layer over a second material layer; etching the first material layer and the second material layer to form a raised structure including a remaining portion of the first material layer and a remaining portion of the second material layer, wherein the remaining portion of the second material layer has a second volume; replacing or converting the second material layer to form a third material layer under the first material layer, wherein the third material layer has a third volume less than the second volume, and wherein the third material layer strains the first material layer to form a strained first material layer; removing the third material layer; and forming a fourth material layer under the strained first material layer.

In certain embodiments of the method, the raised structure extends vertically in a second direction; the remaining portion of the second material layer has a second vertical height in the second direction; before removing the third material layer, the third material layer has a third vertical height in the second direction; and the third vertical height is less than the second vertical height.

In certain embodiments of the method, the raised structure extends laterally in a first direction; the remaining portion of the second material layer has a second width in the first direction; before removing the third material layer, the third material layer has a third width in the first direction; and the third width is less than the second width.

In certain embodiments, the method includes removing the second material layer to form a void under the first material layer; forming a third material precursor in the void under the first material layer; and treating the third material precursor to form the third material layer.

In certain embodiments, the method includes removing a portion of the second material layer, wherein a remaining portion of the second material layer remains under the first material layer; and converting the remaining portion of the second material layer to the third material layer.

In another embodiment, a semiconductor device includes a first source/drain feature distanced from a second source/drain feature in a first direction; a fin structure including a semiconductor nanosheet channel distanced from a mesa portion in a second direction, wherein an upper surface of the mesa portion defines a lateral plane perpendicular to the second direction; a gate structure overlying the fin structure, wherein an under-sheet portion of the gate structure is located between the mesa portion and the semiconductor nanosheet channel of the fin structure; a first inner spacer separating the first source/drain feature from the under-sheet portion; and a second inner spacer separating the second source/drain feature from the under-sheet portion; wherein the semiconductor nanosheet channel has a bottom surface abutting the first inner spacer, the under-sheet portion of the gate structure, and the second inner spacer, wherein the bottom surface has a highest point at a greatest vertical distance from the lateral plane and a lowest point at a shortest vertical distance from the lateral plane; and wherein a difference between the greatest vertical distance and shortest vertical distance is less than three nanometers.

In certain embodiments of the semiconductor device, the difference between the greatest vertical distance and shortest vertical distance is less than one nanometer.

In certain embodiments of the semiconductor device, the semiconductor nanosheet channel has a central region, a first terminal region between the central region and the first inner spacer, and a second terminal region between the central region and the second inner spacer, and a vertical thickness of the central region is greater than a vertical thickness of the first terminal region and is greater than a vertical thickness of the second terminal region.

In certain embodiments of the semiconductor device, the vertical thickness of the central region is from 0.1 to 6 nanometers greater than the vertical thickness of the first terminal region and is 0.1 to 6 nanometers greater than the vertical thickness of the second terminal region.

In certain embodiments of the semiconductor device, the semiconductor nanosheet channel has a central region, a first terminal region between the central region and the first inner spacer, and a second terminal region between the central region and the second inner spacer; a first interface between the central region and the first terminal region is located at a first distance in the first direction from the first source/drain feature; the first distance is from six to twelve nanometers; a second interface between the central region and the second terminal region is located at a second distance in the first direction from the second source/drain feature; and the second distance is from six to twelve nanometers.

In certain embodiments of the semiconductor device, the fin structure includes at least two semiconductor nanosheet channels; the gate structure includes at least two under-sheet portions, wherein each under-sheet portion is located directly below a respective semiconductor nanosheet channel; and each semiconductor nanosheet channel has a vertical thickness of from three to eight nanometers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method comprising:
forming a fin comprising a first material lying over a second material;
forming a sacrificial gate over the fin, wherein a channel region of the fin including the first material and the second material lies directly under the sacrificial gate and between two non-channel regions of the fin including the first material and the second material;
removing the non-channel regions of the fin;
performing a process to replace the second material in the channel region of the fin with a third material;
forming source/drain features in the non-channel regions;
removing the sacrificial gate;
removing the third material; and
forming a gate over the fin.

2. The method of claim 1, further comprising straining the first material with the third material to form a strained first material.

3. The method of claim 1, wherein performing the process to replace the second material with the third material comprises:
removing the second material;
forming a third material precursor under the first material; and
treating the third material precursor to form the third material.

4. The method of claim 1, wherein performing the process to replace the second material with the third material comprises:
removing the second material to form a void under a bottom surface of the first material;
forming a liner on the bottom surface; and
forming the third material under the liner.

5. The method of claim 1, wherein performing the process to replace the second material with the third material comprises:
removing a portion of the second material, wherein a remaining portion of the second material remains under the first material; and
converting the remaining portion of the second material to the third material.

6. The method of claim 5, wherein:
after removing the portion of the second material, a covered surface portion of the first material is covered by the remaining portion of the second material and a non-covered surface portion of the first material is not covered by the remaining portion of the second material;
converting the remaining portion of the second material to the third material comprises performing an oxidation process;
the oxidation process oxidizes the non-covered surface portion of the first material to form a first oxidized material; and
the method further comprises removing at least a portion of the first oxidized material and at least a portion of the third material before forming the source/drain features in the non-channel regions.

7. The method of claim 1, wherein the second material is silicon germanium (SiGe) and wherein the third material is free of germanium.

8. The method of claim 1, wherein:
the fin extends in a first direction;
after removing the non-channel regions of the fin, the second material contacts the first material along an interface having a first length in the first direction;
performing the process to replace the second material with the third material comprises removing at least a portion of the second material;
after performing the process to replace the second material with the third material, the third material in the channel region has a third width in the first direction; and
the third width is less than the first length.

9. The method of claim 1, wherein:
the fin extends in a first direction;
the first material is located over the second material in a second direction perpendicular to the first direction;
before performing the process to replace the second material with the third material, the second material in the channel region has a second vertical thickness in the second direction;
after performing the process to replace the second material with the third material, the third material in the channel region has a third vertical thickness in the second direction; and
the third vertical thickness is less than the second vertical thickness.

10. A method comprising:
forming a first material layer over a second material layer;
etching the first material layer and the second material layer to form a raised structure comprising a remaining portion of the first material layer and a remaining portion of the second material layer, wherein the remaining portion of the second material layer has a second volume;
replacing or converting the second material layer to form a third material layer under the first material layer, wherein the third material layer has a third volume less than the second volume, and wherein the third material layer strains the first material layer to form a strained first material layer;
removing the third material layer; and
forming a fourth material layer under the strained first material layer.

11. The method of claim 10, wherein:
the raised structure extends vertically in a second direction;
the remaining portion of the second material layer has a second vertical height in the second direction;
before removing the third material layer, the third material layer has a third vertical height in the second direction; and
the third vertical height is less than the second vertical height.

12. The method of claim 10, wherein:
the raised structure extends laterally in a first direction;
the remaining portion of the second material layer has a second width in the first direction;
before removing the third material layer, the third material layer has a third width in the first direction; and
the third width is less than the second width.

13. The method of claim 10, wherein the method comprises:
removing the second material layer to form a void under the first material layer;
forming a third material precursor in the void under the first material layer; and
treating the third material precursor to form the third material layer.

14. The method of claim 10, wherein the method comprises:
removing a portion of the second material layer, wherein a remaining portion of the second material layer remains under the first material layer; and
converting the remaining portion of the second material layer to the third material layer.

15. A semiconductor device comprising:
a first source/drain feature distanced from a second source/drain feature in a first direction;
a fin structure including a semiconductor nanosheet channel distanced from a mesa portion in a second direction perpendicular to the first direction, wherein an upper surface of the mesa portion defines a lateral plane perpendicular to the second direction;
a gate structure overlying the fin structure, wherein an under-sheet portion of the gate structure is located between the mesa portion and the semiconductor nanosheet channel of the fin structure;
a first inner spacer separating the first source/drain feature from the under-sheet portion; and
a second inner spacer separating the second source/drain feature from the under-sheet portion;
wherein the semiconductor nanosheet channel has a bottom surface abutting the first inner spacer, the under-sheet portion of the gate structure, and the second inner spacer,
wherein the bottom surface has a highest point at a greatest vertical distance from the lateral plane and a lowest point at a shortest vertical distance from the lateral plane; and
wherein a difference between the greatest vertical distance and shortest vertical distance is less than three nanometers.

16. The semiconductor device of claim 15, wherein the difference between the greatest vertical distance and shortest vertical distance is less than one nanometer.

17. The semiconductor device of claim 15, wherein the semiconductor nanosheet channel has a central region, a first terminal region between the central region and the first inner spacer, and a second terminal region between the central region and the second inner spacer, wherein a vertical thickness of the central region is greater than a vertical thickness of the first terminal region and is greater than a vertical thickness of the second terminal region.

18. The semiconductor device of claim 17, wherein the vertical thickness of the central region is from 0.1 to 6 nanometers greater than the vertical thickness of the first terminal region and is 0.1 to 6 nanometers greater than the vertical thickness of the second terminal region.

19. The semiconductor device of claim 15, wherein:
the semiconductor nanosheet channel has a central region, a first terminal region between the central region and the first inner spacer, and a second terminal region between the central region and the second inner spacer,
a first interface between the central region and the first terminal region is located at a first distance in the first direction from the first source/drain feature;
the first distance is from six to twelve nanometers;
a second interface between the central region and the second terminal region is located at a second distance in the first direction from the second source/drain feature; and
the second distance is from six to twelve nanometers.

20. The semiconductor device of claim 15, wherein:
the fin structure comprises at least two semiconductor nanosheet channels;
the gate structure comprises at least two under-sheet portions, wherein each under-sheet portion is located directly below a respective semiconductor nanosheet channel; and
each semiconductor nanosheet channel has a vertical thickness of from three to eight nanometers.
